(19) United States
(12) Patent Application Publication
(10) Pub. No.: US 2024/0047934 A1
(43) Pub. Date: Feb. 8, 2024

(54) LIGHT-EMITTING DEVICE

(71) Applicant: NICHIA CORPORATION, Tokushima (JP)

(72) Inventor: Tadayuki KITAJIMA, Tokushima (JP)

(21) Appl. No.: 18/364,536

(22) Filed: Aug. 3, 2023

(30) Foreign Application Priority Data
Aug. 5, 2022 (JP) 2022-125198
Feb. 21, 2023 (JP) 2023-025013

(51) Int. Cl. H01S 5/00; H01S 5/40

(52) U.S. Cl. CPC H01S 5/0087; H01S 5/4012

(57) ABSTRACT

A light-emitting device includes first and second semiconductor laser elements configured to respectively emit first and second lights, first and second light reflecting members each having at least four light reflecting surfaces, and a wavelength conversion member including an incident surface on which the reflected first light and the reflected second light are incident. Light intensity distributions in the fast axis direction of the first and second lights on the incident surface are more uniform than light intensity distributions in a fast axis direction of a far-field pattern of each of the first and second semiconductor laser elements. In a state in which the first and second lights are combined on the incident surface, 93% or more of a sum of light outputs of the first and second lights is emitted to a region of a 0.5 mm square on the incident surface.

### CROSS-REFERENCE TO RELATED APPLICATION

This application claims priority to Japanese Patent Application No. 2022-125198 filed on Aug. 5, 2022, and Japanese Patent Application No. 2023-025013 filed on Feb. 21, 2023, the disclosures of which are hereby incorporated herein by reference in their entireties.

### BACKGROUND

The present disclosure relates to a light-emitting device.

Japanese Patent Publication No. 2019-36638 discloses a light-emitting device including a semiconductor laser element, a light reflecting member provided with a light reflecting surface including three regions with different inclination angles, and a fluorescent portion. In this light-emitting device, light emitted from the semiconductor laser element is reflected by the light reflecting surface and emitted to the fluorescent portion. In addition, the light is reflected by the three regions of the light reflecting surface such that a light intensity distribution of the light emitted to the fluorescent portion becomes closer to uniform.

### SUMMARY

There is a need to make a shape of a light extraction surface of the light-emitting device closer to a non-elongated shape such as a circle or a square.

A light-emitting device disclosed in the embodiment includes a first semiconductor laser element, a first light reflecting member, a second semiconductor laser element, a second light reflecting member, and a wavelength conversion member. The first semiconductor laser element is configured to emit first light having a divergence angle of 15 degrees or more and less than 90 degrees in a fast axis direction and a divergence angle of more than 0 degrees and 8 degrees or less in a slow axis direction. The first light reflecting member has at least four light reflecting surfaces sequentially connected in an order of proximity to the first semiconductor laser element. The second semiconductor laser element is configured to emit second light having a divergence angle of 15 degrees or more and less than 90 degrees in a fast axis direction and a divergence angle of more than 0 degrees and 8 degrees or less in a slow axis direction. The second light reflecting member has at least four light reflecting surfaces sequentially connected in an order of proximity to the second semiconductor laser element. The wavelength conversion member has an incident surface on which the first light reflected by the first light reflecting member and the second light reflected by the second light reflecting member are incident. Each part of a main portion of the first light emitted from the first semiconductor laser element is reflected by at least one of the at least four light reflecting surfaces of the first light reflecting member. Each part of a main portion of the second light emitted from the second semiconductor laser element is reflected by at least one of the at least four light reflecting surfaces of the second light reflecting member. A light intensity distribution in the fast axis direction of the first light on the incident surface of the wavelength conversion member is more uniform than a light intensity distribution in a fast axis direction of a far-field pattern of the first semiconductor laser element. A light intensity distribution in the fast axis direction of the second light on the incident surface of the wavelength conversion member is more uniform than a light intensity distribution in a fast axis direction of a far-field pattern of the second semiconductor laser element. In a state where the first light and the second light are combined on the incident surface of the wavelength conversion member, 93% or more of a sum of a light output of the first light and a light output of the second light is emitted to a region of a 0.5 mm square on the incident surface of the wavelength conversion member.

By implementing at least one of one or more disclosures disclosed by the embodiments, a light-emitting device that can efficiently extract light from a light extraction surface having a circular or square shape can be produced.

### BRIEF DESCRIPTION OF DRAWINGS

FIG. 1 is a schematic perspective view of a light-emitting device according to an embodiment.

FIG. 2 is a schematic top view corresponding to FIG. 1.

FIG. 3 is a schematic cross-sectional view of the light-emitting device taken along line in FIG. 2.

FIG. 4A is a schematic top view for explaining an internal structure of the light-emitting device according to the embodiment.

FIG. 4B is an enlarged schematic top view illustrating a positional relationship between a semiconductor laser element, a light reflecting member, and a wavelength conversion member of the light-emitting device according to the embodiment.

FIG. 5A is an FFP in a fast axis direction of light emitted from a first semiconductor laser element according to the embodiment.

FIG. 5B is an FFP in a slow axis direction of the light emitted from the first semiconductor laser element according to the embodiment.

FIG. 5C is an FFP in a fast axis direction of light emitted from a second semiconductor laser element according to the embodiment.

FIG. 5D is an FFP in a slow axis direction of the light emitted from the second semiconductor laser element according to the embodiment.

FIG. 6 is a view showing a simulation of a light intensity distribution of combined light on an incident surface of the wavelength conversion member in the light-emitting device according to the embodiment.

FIG. 7A is a graph showing the light intensity distribution in the X direction of FIG. 6.

FIG. 7B is a graph showing the light intensity distribution in the Y direction of FIG. 6.

FIG. 8A is a view showing a simulation of the light intensity distribution of first light on the incident surface of the wavelength conversion member in the light-emitting device according to the embodiment.

FIG. 8B is a view showing a simulation of the light intensity distribution of second light on the incident surface of the wavelength conversion member in the light-emitting device according to the embodiment.

FIG. 9A is a view obtained by simulating and measuring the light intensity distribution of first partial light of the first light on the incident surface of the wavelength conversion member in the light-emitting device according to the embodiment.

FIG. 9B is a view showing a simulation of the light intensity distribution of the first partial light of the second light on the incident surface of the wavelength conversion member in the light-emitting device according to the embodiment.

FIG. 10A is a view showing a simulation of the light intensity distribution of second partial light of the first light on the incident surface of the wavelength conversion member in the light-emitting device according to the embodiment.

FIG. 10B is a view showing a simulation of the light intensity distribution of the second partial light of the second light on the incident surface of the wavelength conversion member in the light-emitting device according to the embodiment.

FIG. 11A is a view showing a simulation of the light intensity distribution of third partial light of the first light on the incident surface of the wavelength conversion member in the light-emitting device according to the embodiment.

FIG. 11B is a view showing a simulation of the light intensity distribution of the third partial light of the second light on the incident surface of the wavelength conversion member in the light-emitting device according to the embodiment.

FIG. 12A is a view showing a simulation of the light intensity distribution of fourth partial light of the first light on the incident surface of the wavelength conversion member in the light-emitting device according to the embodiment.

FIG. 12B is a view showing a simulation of the light intensity distribution of the fourth partial light of the second light on the incident surface of the wavelength conversion member in the light-emitting device according to the embodiment.

### DETAILED DESCRIPTIONS

In this specification or the claims, polygons such as triangles and quadrangles, including shapes in which the corners of the polygon are rounded, beveled, chamfered, or coved, are referred to as polygons. A shape obtained by processing not only the corners (ends of sides) but also an intermediate portion of a side is similarly referred to as a polygon. That is, a shape that is partially processed while remaining a polygonal shape as a base is included in the interpretation of “polygon” described in this specification and the claims.

The same applies not only to polygons but also to words representing specific shapes such as trapezoids, circles, protrusions, and recessions. The same applies when dealing with each side forming that shape. That is, even if processing is performed on a corner or an intermediate portion of a certain side, the interpretation of “side” includes the processed portion. When a “polygon” or “side” not partially processed is to be distinguished from a processed shape, “exact” will be added to the description as in, for example, “exact quadrangle”.

Furthermore, in this specification or the claims, descriptions such as upper and lower, left and right, front and back, before and after, near and far, and the like are used merely to describe the relative relationship of positions, orientations, directions, and the like, and the expressions need not match an actual relationship at the time of use.

In the drawings, directions such as an X direction, a Y direction, and a Z direction may be indicated by using arrows. The directions of the arrows are consistent across multiple drawings of the same embodiment.

The term “member” or “portion” may be used to describe a component or the like in this specification. The term “member” refers to an object physically treated alone. The object physically treated alone can be an object treated as one part in a manufacturing step. On the other hand, the term “portion” refers to an object that need not be physically treated alone. For example, the term “portion” is used when part of one member is partially regarded.

The distinction between “member” and “portion” described above does not indicate an intention to consciously limit the scope of rights in interpretation of the doctrine of equivalents. That is, even when there is a component described as “member” in the claims, this does not mean that the applicant recognizes that physically treating the component alone is essential in the application of the present disclosure.

In this specification and the claims, when there are a plurality of components and these components are to be indicated separately, the components may be distinguished by adding the terms “first” and “second” at the beginning of the name of the component. Objects to be distinguished may differ between this specification and the claims. Thus, even when a component in the claims is given the same term as that in this specification, the object indicated by that component is not the same across this specification and the claims in some cases.

For example, when there are components distinguished by being termed “first”, “second”, and “third” in this specification, and when components given the terms “first” and “third” in this specification are described in the claims, these components may be distinguished by being denoted as “first” and “second” in the claims for ease of understanding. In this case, the components denoted as “first” and “second” in the claims refer to the components termed “first” and “third” in this specification, respectively. This rule applies to not only components but also other objects in a reasonable and flexible manner.

Embodiments for implementing the present disclosure will be described below. Specific embodiments for implementing the present disclosure will be described below with reference to the drawings. Embodiments for implementing the present disclosure are not limited to the specific embodiments. That is, the illustrated embodiments are not an only form in which the present disclosure is realized. Sizes, positional relationships, and the like of members illustrated in the drawings may sometimes be exaggerated in order to facilitate understanding.

### EMBODIMENT

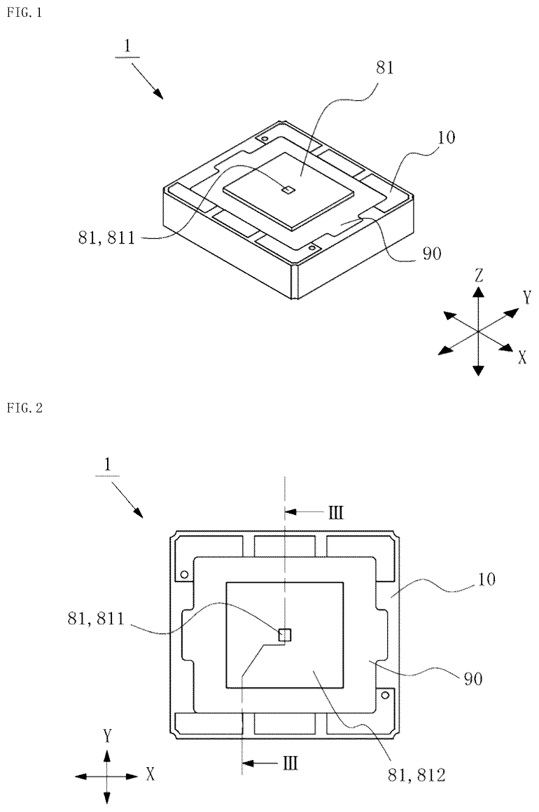

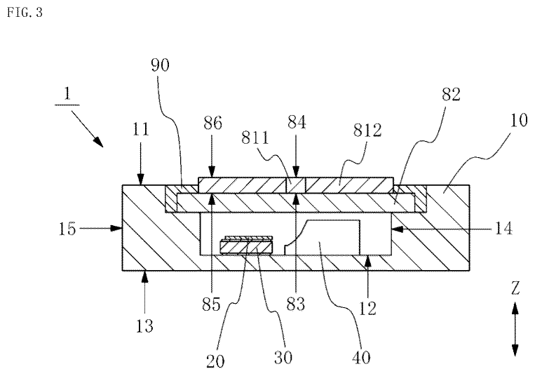

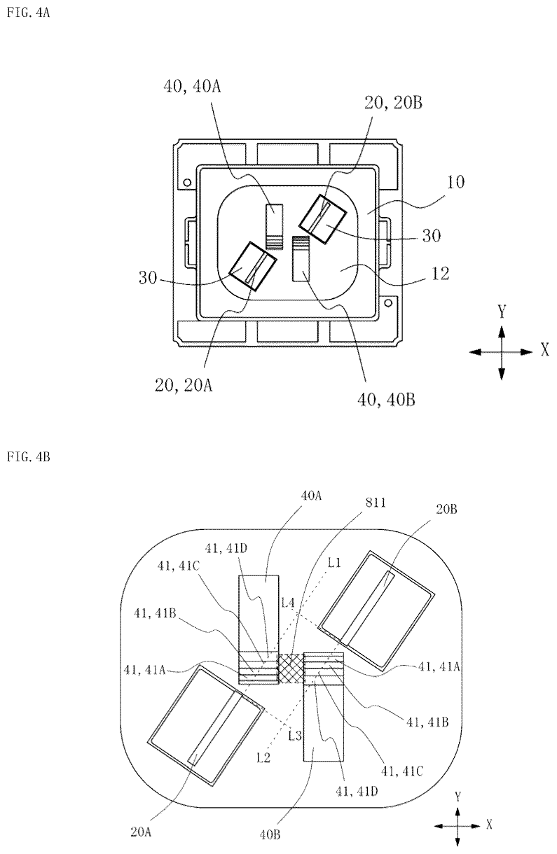

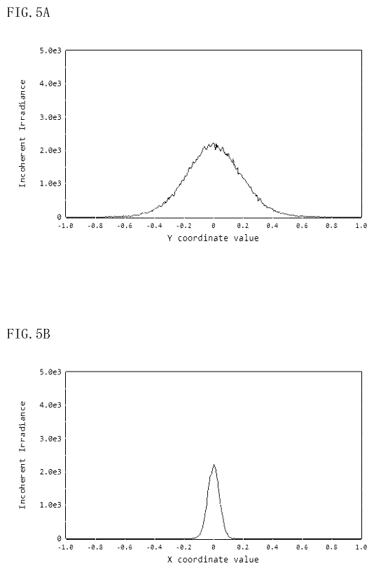

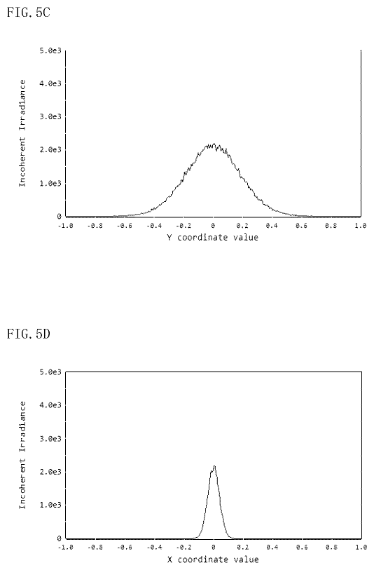

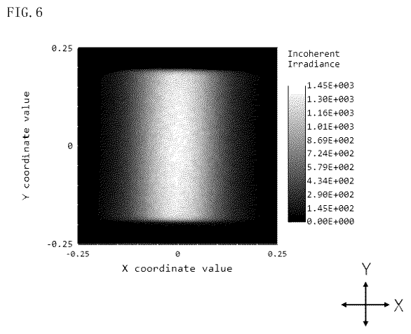

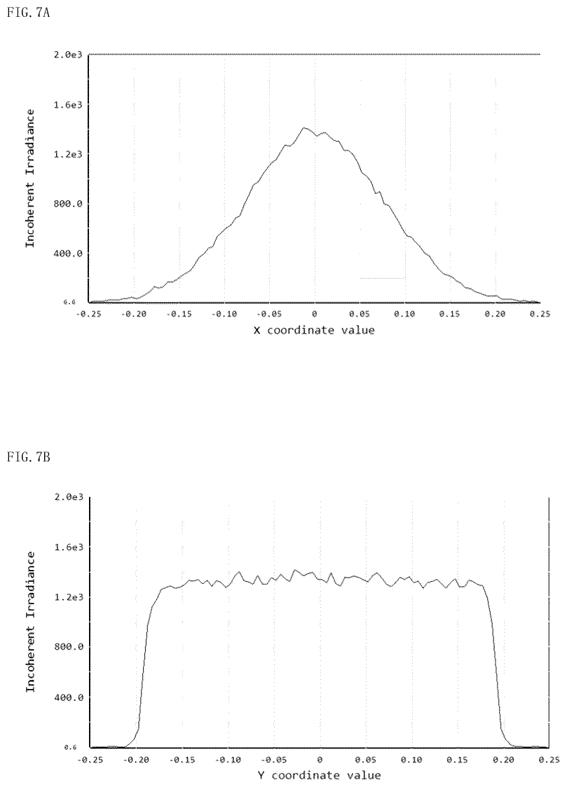

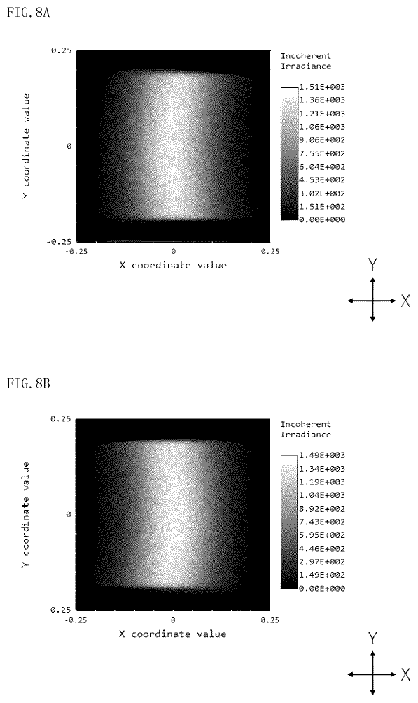

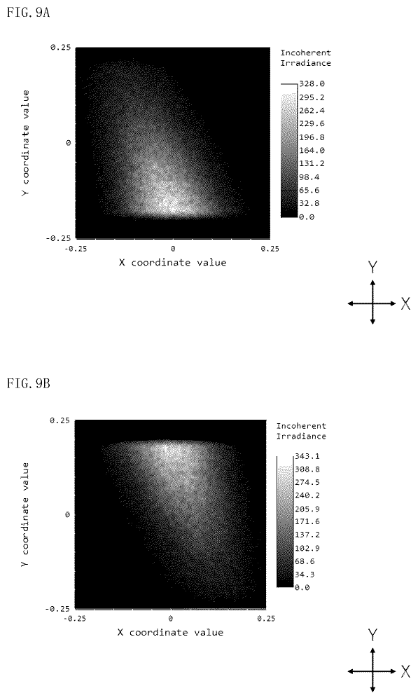

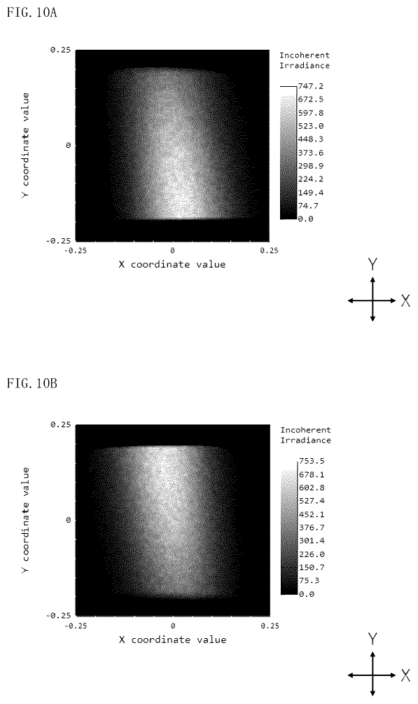

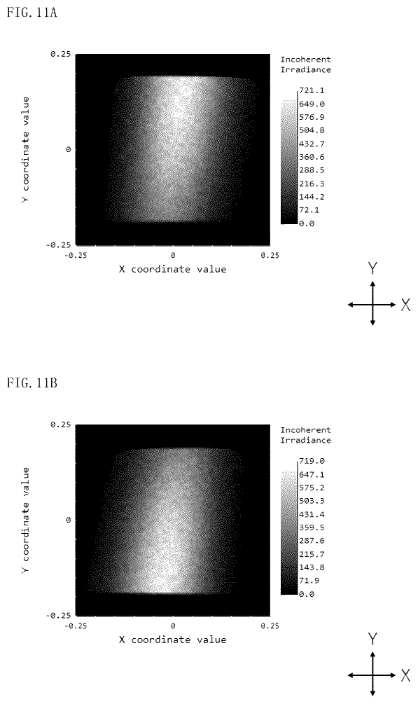

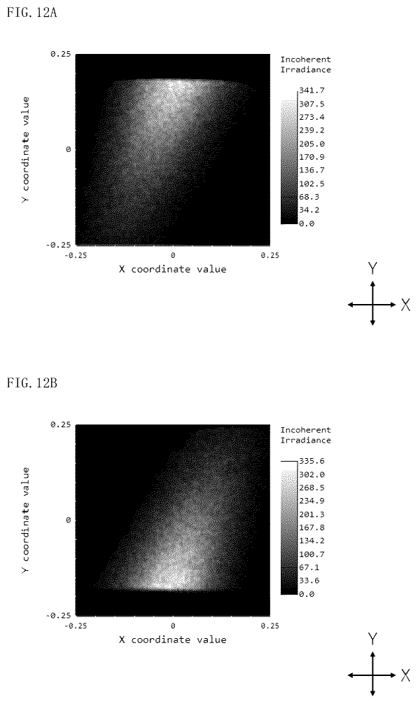

FIGS. 1 to 12B are views for describing a light-emitting device 1 according to the embodiment. FIG. 1 is a schematic perspective view of the light-emitting device 1. FIG. 2 is a schematic top view of the light-emitting device 1. FIG. 3 is a schematic cross-sectional view of the light-emitting device 1 taken along line in FIG. 2. FIG. 4A is a schematic top view for explaining an internal structure of the light-emitting device 1. FIG. 4B is an enlarged schematic top view illustrating an arrangement of a semiconductor laser element 20, a light reflecting member 40, and a wavelength conversion member 81 in the light-emitting device 1. In FIG. 4B, a region where the wavelength conversion member 81 is located in a top view is indicated by hatching. Four virtual straight lines L1, L2, L3, and L4 are indicated by dotted lines. FIGS. 5A and 5B show FFPs of light emitted from a first semiconductor laser element 20A in a fast axis direction and a slow axis direction, respectively. FIGS. 5C and 5D show FFPs of light emitted from a second semiconductor laser element 20B in a fast axis direction and a slow axis direction, respectively. FIG. 6 is a view showing a simulation of a light intensity distribution of combined light on an incident surface 83 of the wavelength conversion member 81 in the light-emitting device 1. FIG. 7A is a view showing the light intensity distribution in the X direction of FIG. 6. FIG. 7B is a view showing the light intensity distribution in the Y direction of FIG. 6. FIG. 8A is a view showing a simulation of the light intensity distribution of first light on the incident surface 83 of the wavelength conversion member 81 in the light-emitting device 1. FIG. 8B is a view showing a simulation of the light intensity distribution of second light on the incident surface 83 of the wavelength conversion member 81 in the light-emitting device 1. FIGS. 9A, 10A, 11A, and 12A are views showing simulations of the light intensity distributions of first partial light, second partial light, third partial light, and fourth partial light of the first light on the incident surface 83 of the wavelength conversion member 81, respectively. FIG. 9B, FIG. 10B, FIG. 11B, and FIG. 12B are views showing simulations of the light intensity distributions of first partial light, second partial light, third partial light, and fourth partial light of the second light on the incident surface 83 of the wavelength conversion member 81, respectively.

Components of the light-emitting device 1 include a base 10, a plurality of semiconductor laser elements 20, one or more submounts 30, a plurality of light reflecting members 40, the wavelength conversion member 81, a light transmissive member 82, and a light blocking member 90. The light-emitting device 1 may further include other components.

Subsequently, each component will be described.

### Base 10

The base 10 includes an upper surface 11, a mounting surface 12, a lower surface 13, one or more inner lateral surfaces 14, and one or more outer lateral surfaces 15. The base 10 has a recessed shape that is recessed downward from above. The base 10 has a rectangular outer shape in a top view.

The mounting surface 12 is a mounting surface on which components are disposed. The mounting surface 12 faces the same side as the upper surface 11 does and is located between the upper surface 11 and the lower surface 13. Further, one or more metal films are provided on each of the upper surface 11 and the mounting surface 12.

The base 10 can be formed of a ceramic as a main material. For example, aluminum nitride, silicon nitride, aluminum oxide, or silicon carbide can be used as the ceramic. A main material of the base 10 is not limited to the ceramic, and any other material having an insulating property may be used as the main material.

### Semiconductor Laser Element 20

The semiconductor laser element 20 has a light-emitting surface from which light is emitted. The semiconductor laser element 20 has an upper surface, a lower surface, and a plurality of lateral surfaces. The lateral surface of the semiconductor laser element 20 serves as a light-emitting surface. The semiconductor laser element 20 emits light laterally from the lateral surface.

A shape of the upper surface of the semiconductor laser element 20 is a rectangle having long sides and short sides. The lateral surface including the short side of this rectangle can be the light-emitting surface. The shape of the upper surface of the semiconductor laser element 20 need not be a rectangle.

The semiconductor laser element 20 emits light having light emission peak wavelengths in a range of 320 nm to 530 nm, typically in a range of 430 nm to 480 nm. An example of the semiconductor laser element 20 that emits such light is a semiconductor laser element including a nitride semiconductor. GaN, InGaN, and AlGaN, for example, can be used as the nitride semiconductor. The light emitted from the semiconductor laser element 20 need not be limited to such a wavelength range.

The semiconductor laser element 20 emits laser light. Divergent light that spreads is emitted from a light-emitting surface (emission end surface) of the semiconductor laser element 20. The light emitted from the semiconductor laser element 20 forms a far-field pattern (hereinafter, referred to as an “FFP”) of an elliptical shape in a plane parallel to the light-emitting surface of the light. The FFP indicates a shape and a light intensity distribution of the emitted light at a position separated from the light-emitting surface.

Here, light passing through the center of the elliptical shape of the FFP, in other words, light having a peak intensity in the light intensity distribution of the FFP is referred to as light traveling along an optical axis or light passing through an optical axis. Based on the light intensity distribution of the FFP, light having an intensity of 1/e² or more with respect to a peak intensity value is referred to as a main portion of the light.

The shape of the FFP of the light emitted from the semiconductor laser element 20 is an elliptical shape in which the light is longer in a layering direction than in a direction perpendicular to the layering direction in the plane parallel to the light-emitting surface of the light. The layering direction is a direction in which a plurality of semiconductor layers including an active layer are layered in the semiconductor laser element 20. The direction perpendicular to the layering direction can also be referred to as a plane direction of the semiconductor layer. A long diameter direction of the elliptical shape of the FFP can also be referred to as a fast axis direction of the semiconductor laser element 20, and a short diameter direction of the elliptical shape of the FFP can also be referred to as a slow axis direction of the semiconductor laser element 20.

Based on the light intensity distribution of the FFP, an angle at which light having a light intensity of 1/e² of a peak light intensity spreads is referred to as a divergence angle of light of the semiconductor laser element 20. For example, a divergence angle of light may also be determined based on the light intensity that is half of the peak light intensity, other than being determined based on the light intensity of 1/e² of the peak light intensity. In the description in this specification, the term “divergence angle of light” itself refers to a divergence angle of light at the light intensity of 1/e² of the peak light intensity. It can be said that a divergence angle in the fast axis direction is greater than a divergence angle in the slow axis direction.

The divergence angle in the fast axis direction of the light emitted from the semiconductor laser element 20 can be 15 degrees or more and less than 90 degrees. In addition, the divergence angle of the light in the slow axis direction can be more than 0 degrees and 8 degrees or less. The angle of the divergence angle of light is represented by an angle with respect to the optical axis.

### Submount 30

The submount 30 includes a lower surface, an upper surface, and one or more lateral surfaces. The submount 30 has the smallest width in a vertical direction. the submount 30 is formed in a rectangular parallelepiped shape. The shape need not be limited to a rectangular parallelepiped. The submount 30 is formed using, for example, silicon nitride, aluminum nitride, or silicon carbide. Other materials may be used.

### Light Reflecting Member 40

The light reflecting member 40 has a plurality of light reflecting surfaces 41 that reflect light. The light reflecting member 40 has at least four light reflecting surfaces 41. These four light reflecting surfaces 41 are sequentially connected to each other. When these four light reflecting surfaces 41 are distinguished from one another, they are referred to as a first light reflecting surface 41A, a second light reflecting surface 41B, a third light reflecting surface 41C, and a fourth light reflecting surface 41D. Each of the light reflecting surfaces 41 can have a light reflectance of 90% or more at the peak wavelength of the emitted light. The light reflectance may be 100% or less, or may be less than 100%.

The light reflecting member 40 has a lower surface. The light reflecting surface 41 is inclined with respect to the lower surface of the light reflecting member 40. The light reflecting surface 41 is a flat surface. The inclination angle of the light reflecting surface 41 refers to an inclination angle of the light reflecting surface 41 with respect to the lower surface of the light reflecting member 40. The four light reflecting surfaces 41A, 41B, 41C, and 41D have inclination angles different from each other.

Among the four light reflecting surfaces 41A, 41B, 41C, and 41D, the first light reflecting surface 41A is located at the lowest position, and the fourth light reflecting surface 41D is located at the highest position. The first light reflecting surface 41A and the second light reflecting surface 41B are connected to each other, the second light reflecting surface 41B and the third light reflecting surface 41C are connected to each other, and the third light reflecting surface 41C and the fourth light reflecting surface 41D are connected to each other, whereby the four light reflecting surfaces 41A, 41B, 41C, and 41D are connected and provided.

In each of the light reflecting surfaces 41, a length of the light reflecting surface 41 in an inclination direction is referred to as a width of the light reflecting surface 41. In the four light reflecting surfaces 41A, 41B, 41C, and 41D, the width of the light reflecting surface 41 is smaller as the light reflecting surface 41 is located at a lower position. Here, a direction passing through an intersection line when a virtual plane parallel to the lower surface of the light reflecting member 40 intersects with the light reflecting surface 41 is referred to as a parallel direction of the light reflecting surface 41. In each of the light reflecting surfaces 41, the parallel direction of the light reflecting surface 41 is perpendicular to the inclination direction of the light reflecting surface 41. Hereinafter, the parallel direction of the light reflecting surface 41 is referred to as a first direction, and the inclination direction of the light reflecting surface 41 is referred to as a second direction. The second directions of the light reflecting surfaces 41 having different inclination angles are different from each other.

The inclination angle of each of the light reflecting surfaces 41 is in a range of 10 degrees to 80 degrees. The inclination angle of the first light reflecting surface 41A (hereinafter referred to as a first inclination angle) may be in a range of 20 degrees to 35 degrees. The inclination angle of the second light reflecting surface 41B (hereinafter referred to as a second inclination angle) may be in a range of 30 degrees to 45 degrees. The inclination angle of the third light reflecting surface 41C (hereinafter referred to as a third inclination angle) may be in a range of 45 degrees to 60 degrees. The inclination angle of the fourth light reflecting surface 41D (hereinafter referred to as a fourth inclination angle) may be in a range of 55 degrees to 70 degrees.

A difference between the first inclination angle and the second inclination angle may be in a range of 8 degrees to 14 degrees. A difference between the second inclination angle and the third inclination angle may be in a range of 9 degrees to 15 degrees. A difference between the third inclination angle and the fourth inclination angle may be in a range of 10 degrees to 16 degrees.

The difference between the first inclination angle and the second inclination angle is smaller than the difference between the second inclination angle and the third inclination angle. The difference between the second inclination angle and the third inclination angle is larger than the difference between the first inclination angle and the second inclination angle by a range of 0.5 degrees to 3 degrees. The difference between the second inclination angle and the third inclination angle is smaller than the difference between the third inclination angle and the fourth inclination angle. The difference between the third inclination angle and the fourth inclination angle is larger than the difference between the second inclination angle and the third inclination angle by a range of 0.5 degrees to 3 degrees.

For the light reflecting member 40, glass, metal, or the like can be used as a main material of an outer shape thereof. The main material is preferably a heat-resistant material, and for example, glass such as quartz or BK7 (borosilicate glass), a metal such as aluminum, or Si can be used. The light reflecting surface can be formed using, for example, a metal such as Ag or Al, or a dielectric multilayer film of Ta₂O₅/SiO₂, TiO₂/SiO₂, Nb₂O₅/SiO₂, or the like.

### Wavelength Conversion Member 81

The wavelength conversion member 81 has an upper surface, a lower surface, and one or more lateral surfaces. The wavelength conversion member 81 has an incident surface 83 on which light is incident. The wavelength conversion member 81 has an emission surface 84 from which light exits. The emission surface 84 is opposite to the incident surface 83. In the illustrated wavelength conversion member 81, the lower surface of the wavelength conversion member 81 serves as the incident surface 83, and the upper surface of the wavelength conversion member 81 serves as the emission surface 84.

The wavelength conversion member 81 includes: a wavelength conversion portion 811 having the incident surface 83 and the emission surface 84; and a surrounding portion 812 surrounding the wavelength conversion portion 811. The surrounding portion 812 has a first surface 85 surrounding the incident surface 83 in a plan view seen from a direction perpendicular to the incident surface 83. The surrounding portion 812 has a second surface 86 surrounding the emission surface 84 in a plan view seen from a direction perpendicular to the emission surface 84. The surrounding portion 812 does not include the incident surface 83 and the emission surface 84 of the wavelength conversion member 81.

The inner lateral surface of the surrounding portion 812 is in contact with the lateral surface of the wavelength conversion portion 811, and one or more lateral surfaces of the wavelength conversion portion 811 are surrounded by the surrounding portion 812. One or more outer lateral surfaces of the surrounding portion 812 correspond to one or more lateral surfaces of the wavelength conversion member 81.

The wavelength conversion member 81 contains a phosphor. The wavelength conversion portion 811 contains the phosphor. The surrounding portion 812 does not contain a phosphor.

The outer shape of the incident surface 83 is a square. The square here includes the case in which a ratio of the lengths of two sides perpendicular to each other in the square is in a range of 95% to 105%. The term “perpendicular” includes a tolerance of 5 degrees or less. The outer shape of the incident surface 83 need not be a square. The outer shape of incident surface 83 may be a rectangle having a first side and a second side perpendicular to the first side, and a length of the first side may be in a range of 1.0 times to 1.5 times a length of the second side. The incident surface 83 may have a size such that it does not protrude from a 0.75 mm square. Alternatively, the incident surface 83 may have a size such that it does not protrude from a 0.55 mm square.

The outer shape of the emission surface 84 is a square. The square here includes the case in which a ratio of the lengths of two sides perpendicular to each other in the square is in a range of 95% to 105%. The outer shape of the emission surface 84 need not be a square. The outer shape of the emission surface 84 is the same as the outer shape of the incident surface 83. The outer shape of the emission surface 84 may not be the same as the outer shape of the incident surface 83. The emission surface 84 may have a size such that it does not protrude from a 0.75 mm square. Alternatively, the emission surface 84 may have a size such that it does not protrude from a 0.55 mm square.

In the wavelength conversion member 81, the wavelength conversion portion 811 and the surrounding portion 812 are monolithically formed. The wavelength conversion portion 811 and the surrounding portion 812 can be formed using, as a main material, an inorganic material that is not easily decomposed by light irradiation. The material need not be an inorganic material.

The wavelength conversion member 81 is formed of a monolithically sintered body in which the wavelength conversion portion 811 and the surrounding portion 812 are monolithically sintered. Such a monolithic sintered body can form the base material of the wavelength conversion member 81 when the wavelength conversion portion 811 formed of a molded product such as a sintered body and a material of powder particles forming the surrounding portion 812 are monolithically molded and sintered, for example. For sintering, for example, an atmospheric pressure sintering method, a spark plasma sintering method (SPS method), a hot press sintering method (HP method), or the like can be used.

The wavelength conversion portion 811 converts the incident light into light having a different wavelength. The wavelength conversion portion 811 emits light whose wavelength has been converted into a different wavelength. Part of the incident light is emitted from the wavelength conversion portion 811 without being converted by the wavelength conversion portion 811.

The wavelength conversion portion 811 can be formed using the ceramic as a main material and contain a phosphor. Alternatively, glass may be used as the main material. Alternatively, the wavelength conversion portion 811 may be formed using a polycrystal of a simple substance of a phosphor or a single crystal of a phosphor.

For example, when a ceramic is used as the main material of the wavelength conversion portion 811, the wavelength conversion portion 811 can be formed by sintering a phosphor and a light transmissive material such as aluminum oxide. The content of the phosphor can be in a range of 0.05 vol % to 50 vol % with respect to the total volume of the ceramic. Further, for example, a ceramic formed of substantially only a phosphor obtained by sintering powder of the phosphor may be used.

Examples of the phosphor include cerium-activated yttrium aluminum garnet (YAG), cerium-activated lutetium aluminum garnet (LAG), europium- and/or chromium-activated nitrogen-containing calcium aluminosilicate (CaO—Al₂O₃—SiO₂), europium-activated silicate ((Sr,Ba)₂SiO₄), α-SiAlON phosphor, and β-SiAlON phosphor. In particular, it is preferable to use a YAG phosphor, which has good heat resistance and can emit white light in combination with blue excitation light.

The surrounding portion 812 has a shape in which a through hole is formed in a central portion of a rectangular parallelepiped flat plate. The wavelength conversion portion 811 is provided closing the through hole. The surrounding portion 812 can be formed by using a ceramic as a main material. No such limitation is intended, and a metal, a composite of a ceramic and a metal, or the like may be used.

### Light Transmissive Member 82

The light transmissive member 82 has a lower surface, an upper surface, and one or more lateral surfaces. The light transmissive member 82 is light transmissivity. Here, “light transmissive” means that the light transmittance is 80% or more. The light transmissive member 82 includes a base material formed in a rectangular parallelepiped flat plate shape. The shape is not limited to a rectangular parallelepiped.

The light transmissive member 82 can be formed using sapphire as a main material. Sapphire is a material with relatively high transmittance and relatively high strength. Other than sapphire, for example, quartz, silicon carbide, glass, or the like may be used as the main material.

### Light Blocking Member 90

The light blocking member 90 is formed of a resin having a light blocking property. The light blocking property indicates a property of transmitting substantially no light and may be achieved by using a light absorbing property, a light reflective property, or the like, other than the light blocking property. The light blocking member 90 can be formed, for example, by adding a filler such as a light diffusing material and/or a light absorbing material in resin.

Examples of the resin forming the light blocking member 90 include an epoxy resin, a silicone resin, an acrylate resin, a urethane resin, a phenol resin, and a BT resin. Examples of the light absorbing filler include dark-colored pigments such as carbon black.

### Light-Emitting Device 1

Subsequently, the light-emitting device 1 will be described.

In the light-emitting device 1, the plurality of semiconductor laser elements 20 are disposed on the mounting surface 12 of the base 10. Each of the plurality of semiconductor laser elements 20 is disposed on the mounting surface 12 with the submount 30 interposed therebetween.

The plurality of semiconductor laser elements 20 include the first semiconductor laser element 20A and the second semiconductor laser element 20B. The light-emitting surface of the first semiconductor laser element 20A and the light-emitting surface of the second semiconductor laser element 20B are parallel to each other. The term parallel here includes a tolerance of ±5 degrees.

The second semiconductor laser element 20B is not disposed on the first virtual straight line L1 passing through the light-emitting surface of the first semiconductor laser element 20A and being perpendicular to this light-emitting surface. The first semiconductor laser element 20A is not disposed on a second virtual straight line L2 passing through the light-emitting surface of the second semiconductor laser element 20B and being perpendicular to this light-emitting surface. The first virtual straight line L1 and the second virtual straight line L2 are parallel to each other. The term parallel here includes a tolerance of ±5 degrees.

In the light-emitting device 1, the plurality of light reflecting members 40 are disposed on the mounting surface 12 of the base 10. The lower surface of each of the light reflecting members 40 is joined to the base 10. The inclination angle of the light reflecting surface 41 with respect to the mounting surface 12 is the same as the inclination angle of the light reflecting surface 41 with respect to the lower surface of the light reflecting member 40. Here, “the same” includes a deviation from parallelism in a case in which the mounting surface 12 and the lower surface of the light reflecting member 40 are not parallel to each other at the time of joining.

The plurality of light reflecting members 40 include a first light reflecting member 40A and a second light reflecting member 40B. The first light reflecting member 40A reflects light emitted from the first semiconductor laser element 20A (hereinafter referred to as first light). The second light reflecting member 40B reflects light emitted from the second semiconductor laser element 20B (hereinafter referred to as second light). The first light reflecting member 40A is disposed on the first virtual straight line L1, and the second light reflecting member 40B is disposed on the second virtual straight line L2.

In a top view, the first direction and the second direction of the first light reflecting member 40A are neither perpendicular nor parallel to the first virtual straight line L1. In a top view, the first direction and the second direction of the second light reflecting member 40B are neither perpendicular nor parallel to the second virtual straight line L2.

In a top view, the first semiconductor laser element 20A and the first light reflecting member 40A, and the second semiconductor laser element 20B and the second light reflecting member 40B are disposed symmetrically. These are disposed point-symmetrically with respect to a point at which (i) a virtual straight line connecting the same portions of the first semiconductor laser element 20A and the second semiconductor laser element 20B and (ii) a virtual straight line connecting the same portions of the first light reflecting member 40A and the second light reflecting member 40B intersect.

The first light reflecting member 40A is disposed such that the first light reflecting surface 41A, the second light reflecting surface 41B, the third light reflecting surface 41C, and the fourth light reflecting surface 41D are located closer to the first semiconductor laser element 20A in this order. Therefore, for the four light reflecting surfaces 41A, 41B, 41C, and 41D of the first light reflecting member 40A, it can be said that the width of the light reflecting surface is larger as the light reflecting surface 41 is positioned farther from the first semiconductor laser element 20A.

The second light reflecting member 40B is disposed such that the first light reflecting surface 41A, the second light reflecting surface 41B, the third light reflecting surface 41C, and the fourth light reflecting surface 41D are located closer to the second semiconductor laser element 20B in this order. Therefore, for the four light reflecting surfaces 41A, 41B, 41C, and 41D of the second light reflecting member 40B, it can be said that the width of the light reflecting surface is larger as the light reflecting surface 41 is positioned farther from the second semiconductor laser element 20B. The first light reflecting surface 41A, the second light reflecting surface 41B, the third light reflecting surface 41C, and the fourth light reflecting surface 41D of the second light reflecting member 40B may be referred to as a fifth light reflecting surface, a sixth light reflecting surface, a seventh light reflecting surface, and an eighth light reflecting surface, respectively, in order to be distinguished from the first light reflecting surface 41A, the second light reflecting surface 41B, the third light reflecting surface 41C, and the fourth light reflecting surface 41D of the first light reflecting member 40A.

Each part of the main portion of the light emitted from the first semiconductor laser element 20A is reflected by at least one of the at least four light reflecting surfaces 41A, 41B, 41C, and 41D of the first light reflecting member 40A. Each part of the main portion of the light emitted from the second semiconductor laser element 20B is reflected by at least one of the at least four light reflecting surfaces 41A, 41B, 41C, 41D of the second light reflecting member 40B.

In the light-emitting device 1, the wavelength conversion member 81 is disposed on the base 10. The wavelength conversion member 81 is supported by the base 10. The wavelength conversion member 81 is fixed to the base 10 with the light transmissive member 82 interposed therebetween. The light transmissive member 82 is joined to the base 10, and the wavelength conversion member 81 is joined to the light transmissive member 82. The wavelength conversion member 81 may be joined to the base 10 without the light transmissive member 82 interposed therebetween. The wavelength conversion member 81 is located above the mounting surface 12. The wavelength conversion member 81 is located above the plurality of semiconductor laser elements 20 and the plurality of light reflecting members 40.

The incident surface 83 of the wavelength conversion member 81 is located at a position through which a virtual straight line connecting a point on the light-emitting surface of the first semiconductor laser element 20A and a point on the light-emitting surface of the second semiconductor laser element 20B passes in a top view. The incident surface 83 is located so as to fit inside a quadrangular region surrounded by, in a top view, a virtual straight line L3 parallel to the light-emitting surface of the first semiconductor laser element 20A and passing through this light-emitting surface, a virtual straight line L4 parallel to the light-emitting surface of the second semiconductor laser element 20B and passing through this light-emitting surface, the first virtual straight line L1, and the second virtual straight line L2.

The emission surface 84 of the wavelength conversion member 81 is located at a position through which a virtual straight line connecting a point on the light-emitting surface of the first semiconductor laser element 20A and a point on the light-emitting surface of the second semiconductor laser element 20B passes in a top view. The emission surface 84 is located so as to fit inside a quadrangular region surrounded by the virtual straight line L3, the virtual straight line L4, the first virtual straight line L1, and the second virtual straight line L2 in a top view.

The first light reflected by the first light reflecting member 40A and the second light reflected by the second light reflecting member 40B are incident on the incident surface 83. Light emitted from each of the plurality of semiconductor laser elements 20 is incident on the incident surface 83. The main portion of the light emitted from each of the plurality of semiconductor laser elements 20 is incident on the incident surface 83.

Light obtained by wavelength conversion of the light incident on the incident surface 83 of the wavelength conversion member 81 is emitted from the emission surface 84. Part of the light incident on the incident surface 83 may pass through the wavelength conversion member 81 without being subjected to wavelength conversion, and may be emitted from the emission surface 84. For example, in the light-emitting device 1, blue light emitted from the semiconductor laser element 20 is incident on the incident surface 83, part of the blue light is subjected to wavelength conversion into yellow light in the wavelength conversion member 81, and white light in which the blue light and the yellow light are mixed can be emitted from the emission surface 84. The emission surface 84 of the wavelength conversion member 81 can be referred to as a light extraction surface of the light-emitting device 1.

Each of the light reflecting members 40 reflects the light emitted from the semiconductor laser element 20 such that the light is incident on the wavelength conversion portion 811. 95% or more of the main portion of the light emitted from the semiconductor laser element 20 is incident on the wavelength conversion portion 811. The first surface 85 of the surrounding portion 812 blocks most of the incident light so that the incident light is not emitted from the second surface 86. For example, the surrounding portion 812 blocks 90% or more of the light incident on the first surface 85.

As shown in FIGS. 8A and 8B as examples, the light emitted from each of the semiconductor laser elements 20 is reflected by the light reflecting member 40, so that the distribution shape of the light emitted to the incident surface 83 becomes a shape closer to a rectangle (referred to as a first characteristic). Further, as shown in FIGS. 8A and 8B, the light emitted from each of the semiconductor laser elements 20 is reflected by the light reflecting member 40, thereby being further uniformed and emitted to the incident surface 83 (referred to as a second characteristic).

By satisfying the first characteristic, light can be efficiently incident on the incident surface 83 having a shape closer to a rectangle (including a rectangle itself). By satisfying the second characteristic, it is possible to contribute to suppression of a decrease in the light conversion efficiency of the wavelength conversion member 81 or reduction of unevenness in the emission intensity of light emitted from the wavelength conversion member 81.

The light distribution shapes shown in FIGS. 8A and 8B are slightly curved, but can be said to be closer to a rectangle than to the elliptical shape of the FFP. It can be seen that the light intensity distribution in a direction parallel to one side (hereinafter, referred to as a third side) of two sides perpendicular to each other in a minimum rectangle (hereinafter, referred to as an enclosing rectangle) including the distribution shape is more uniform than the light intensity distribution in the fast axis direction of the FFP is. Here, the third side is a side closer to parallel or substantially parallel to a third virtual straight line connecting points on the incident surface 83 to which two light paths (referred to as first end light passing through one light path and second end light passing through the other light path) of portions passing through both ends in the fast axis direction of the FFP of the lights emitted from the semiconductor laser element 20 are emitted. The term “closer to parallel” or “substantially parallel” means that the angle formed by the virtual straight line and one of the two sides is closer to 0 degrees. A direction parallel to the third virtual straight line is defined as a fast axis direction of light on the incident surface 83, and is simply referred to as a virtual fast axis direction. The enclosing rectangle can be specified based on the light that is the main portion of the light and is reflected by the four light reflecting surfaces 41A, 41B, 41C, and 41D.

The third virtual straight line may be obtained based on light having a light intensity of a half value of the peak intensity value existing in both of the plus direction and the minus direction of the fast axis direction of the FFP from the center of the FFP, instead of the light of the portion passing through both ends in the fast axis direction of the FFP.

It can also be said that the second characteristic is that the light intensity distribution in the virtual fast axis direction of the light emitted from the semiconductor laser element(s) 20 is more uniform than the light intensity distribution in the fast axis direction of the FFP(s) of the semiconductor laser element(s) 20 is.

Here, the “more uniform state” in the second characteristic may be defined based on the ratio of the width across both ends indicating the light intensity of 80% of the peak light intensity to the width across both ends indicating the light intensity of 1/e² of the peak light intensity in the light intensity distribution.

For example, a state in which the ratio in the light emitted to the incident surface 83 is higher than the ratio in the FFP of the semiconductor laser element 20 by 20% or more may be the “more uniform state” in the second characteristic. Further, for example, a state in which the ratio in the light emitted to the incident surface 83 is higher than the ratio in the FFP of the semiconductor laser element 20 by 40% or more may be the “more uniform state” in the second characteristic.

For example, a state in which the ratio in the light emitted to the incident surface 83 is 50% or more may be the “more uniform state” in the second characteristic. For example, a state in which the ratio in the light emitted to the incident surface 83 is 70% or more may be the “more uniform state” in the second characteristic. For example, a state in which the ratio in the light emitted to the incident surface 83 is 90% or more may be the “more uniform state” in the second characteristic.

In the illustrated light-emitting device 1, the third virtual straight line is parallel to the third side. Therefore, the slow axis direction of light on the incident surface 83 is parallel to the other side (hereinafter, referred to as a fourth side) of the two sides of the enclosing rectangle. Further, the first side of the incident surface 83 is parallel to the third side. Therefore, the second side and the fourth side of the incident surface 83 are parallel to each other.

In the light-emitting device 1, the first side and the third virtual straight line can be parallel to each other regardless of whether or not the first side and the third side are parallel to each other. The second side and the third virtual straight line can be perpendicular to each other regardless of whether or not the second side and the fourth side are parallel to each other.

In the enclosing rectangle based on the distribution shape of the first light on the incident surface 83, the length of the third side is in a range of 1.0 times to 1.5 times, preferably of 1.0 times to 1.3 times the length of the fourth side. As a result, the incident surface 83 can be formed in a shape closer to a non-elongated shape, and the light extraction surface of the light-emitting device can be made closer to a non-elongated shape.

In the enclosing rectangle based on the distribution shape of the second light on the incident surface 83, the length of the third side is in a range of 1.0 times to 1.5 times, preferably from 1.0 times to 1.3 times the length of the fourth side. As a result, the incident surface 83 can be formed in a shape closer to a non-elongated shape, and the light extraction surface of the light-emitting device can be made closer to a non-elongated shape.

With respect to light in a state in which the first light and the second light are combined on the incident surface 83 (hereinafter, referred to as combined light), the length of the third side is in a range of 1.0 times to 1.5 times, preferably from 1.0 times to 1.2 times the length of the fourth side in the enclosing rectangle based on the distribution shape of the combined light. As a result, the shape of the incident surface 83 can be made closer to a non-elongated shape, and the light extraction surface of the light-emitting device can be made closer to a non-elongated shape.

For example, in a case in which light having an elliptical shape emitted from the semiconductor laser element 20 is handled, when an incident surface and a light extraction surface having a shape close to a non-elongated shape are provided while uniformity is required, the degree of proximity to the non-elongated shape varies depending on the number of light reflecting surfaces. For example, as a result of simulation by the present inventors, when the same semiconductor laser element as the semiconductor laser element 20 of the light-emitting device 1 in the present disclosure is used and the light reflecting member has three light reflecting surfaces each of which is a flat surface as exemplified in Japanese Patent Publication No. 2019-36638, the length of the third side is twice or more the length of the fourth side, and it is difficult to make the length of the third side 1.5 times or less the length of the fourth side.

In the light-emitting device 1, 93% or more of the light output [W] of the combined light (the sum of the light output [W] of the first light and the light output [W] of the second light) is emitted to a region of 0.5 mm square on the incident surface 83. As a result, the light extraction surface of the light-emitting device 1 can be made closer to a non-elongated shape. In addition, the light can be efficiently taken into a region of 0.5 mm square, and the light can be emitted from the light extraction surface having a small size of about 0.5 mm square. The sizes of the incident surface 83 and the emission surface 84 may be larger than a 0.5 mm square.

It is preferable that a larger amount of light is emitted to the region of 0.5 mm square on the incident surface 83. In the light-emitting device 1, 95% or more of the light output [W] of the combined light (the sum of the light output [W] of the first light and the light output [W] of the second light) can be emitted to the region of 0.5 mm square on the incident surface 83. Alternatively, in the light-emitting device 1, 98% or more of the light output [W] of the combined light (the sum of the light output [W] of the first light and the light output [W] of the second light) can be emitted to the region of 0.5 mm square on the incident surface 83.

According to the light-emitting device 1, light output that would be taken into the region of 1.0 mm square if the light reflecting member has three flat light reflecting surfaces as exemplified in Japanese Patent Publication No. 2019-36638 can be taken into the region of 0.5 mm square.

All of the semiconductor laser elements 20 need not satisfy these two characteristics. For example, the first semiconductor laser element 20A and the second semiconductor laser element 20B can satisfy at least the first characteristic. For example, the first semiconductor laser element 20A and the second semiconductor laser element 20B can satisfy at least the second characteristic. For example, the first semiconductor laser element 20A can satisfy at least the first characteristic, and the second semiconductor laser element 20B can satisfy at least the second characteristic. In the illustrated light-emitting device 1, both the first semiconductor laser element 20A and the second semiconductor laser element 20B satisfy the first characteristic and the second characteristic.

In the light-emitting device 1, the difference between the first inclination angle and the second inclination angle and the difference between the second inclination angle and the third inclination angle are each 3 degrees or less, whereby the second characteristic can be satisfied in a smaller region. Similarly, the difference between the second inclination angle and the third inclination angle and the difference between the third inclination angle and the fourth inclination angle are each 3 degrees or less, whereby the second characteristic can be satisfied in a smaller region.

Of the light reflected by the four light reflecting surfaces 41A, 41B, 41C, and 41D and emitted to the incident surface 83, a portion reflected by the first light reflecting surface 41A and emitted to the incident surface 83 is referred to as first partial light, a portion reflected by the second light reflecting surface 41B and emitted to the incident surface 83 is referred to as second partial light, a portion reflected by the third light reflecting surface 41C and emitted to the incident surface 83 is referred to as third partial light, and a portion reflected by the fourth light reflecting surface 41D and emitted to the incident surface 83 is referred to as fourth partial light.

The light output [W] of the first partial light can be in a range of 5% to 20% of the light output [W] of the light emitted from the semiconductor laser element 20. The light output [W] of the second partial light can be in a range of 30% to 45% of the light output [W] of the light emitted from the semiconductor laser element 20. The light output [W] of the third partial light can be in a range of 30% to 45% of the light output [W] of the light emitted from the semiconductor laser element 20. The light output [W] of the fourth partial light can be in a range of 5% to 20% of the light output [W] of the light emitted from the semiconductor laser element 20.

An area of an overlap between a region (hereinafter, referred to as a first region) of the incident surface 83 that is irradiated with the first partial light of the main portion of the first light and a region of the incident surface 83 that is irradiated with the first partial light of the main portion of the second light may be in a range of 0% to 60% of the area of the first region. Alternatively, the area of the overlap may be in a range of 0% to 40% of the area of the first region.

An area of an overlap between a region (hereinafter referred to as a second region) of the incident surface 83 that is irradiated with the second partial light of the main portion of the first light and a region of the incident surface 83 that is irradiated with the second partial light of the main portion of the second light can be 75% or more and less than 100% of the area of the second region. Alternatively, the area of the overlap may be 90% or more and less than 100% of the area of the second region.

An area of an overlap between a region (hereinafter, referred to as a third region) of the incident surface 83 that is irradiated with the third partial light of the main portion of the first light and a region of the incident surface 83 that is irradiated with the third partial light of the main portion of the second light may be 75% or more and less than 100% of the area of the third region. Alternatively, the area of the overlap may be 90% or more and less than 100% of the area of the third region. Also, the area of the overlap may be 90% or more and less than 100% of the area of the second region.

An area of an overlap between a region (hereinafter, referred to as a fourth region) of the incident surface 83 that is irradiated with the fourth partial light of the main portion of the first light and a region of the incident surface 83 that is irradiated with the fourth partial light of the main portion of the second light may be in a range of 0% to 60% of the area of the fourth region. Alternatively, the area of the overlap may be in a range of 0% to 40% of the area of the fourth region. Also, the area of the overlap may be in a range of 0% to 40% of the area of the first region.

As described above, in the light-emitting device 1, with respect to the area of an overlap between the first light and the second light on the incident surface 83, the area of an overlap between the first partial lights is smaller than the area of an overlap between the second partial lights. Further, the area of an overlap between the fourth partial lights is smaller than the area of an overlap between the third partial lights.

Due to the symmetry of the arrangement of the first semiconductor laser element 20A, the second semiconductor laser element 20B, the first light reflecting member 40A, and the second light reflecting member 40B, the first partial light of the first semiconductor laser element 20A and the first partial light of the second semiconductor laser element 20B also have symmetrical distributions on the incident surface 83. The same applies to the second partial lights, the third partial lights, and the fourth partial lights. The term symmetry here is not limited to symmetry in a strict sense. The first partial light and the fourth partial light have lower light intensity than the second partial light and the third partial light, and as can be seen from the light intensity distribution of the FFP, the change in the light intensity with respect to the change in the angle at which the light spreads is gradual. In this manner, in consideration of the symmetry and the property of the intensity distribution of light, the uniformity of the combined light of the first partial lights and the uniformity of the combined light of the fourth partial lights can be improved when the ratio of the area of an overlap between the first partial lights and the ratio of the area of an overlap between the fourth partial lights are not too high. On the other hand, the uniformity of the combined light of the second partial lights and the uniformity of the combined light of the third partial lights can be improved by increasing the ratio of the area of an overlap between the second partial lights and the ratio of the area of an overlap between the third partial lights.

This can be influenced by the fact that the distribution shapes of the first partial light and the fourth partial light are closer to a triangle than to a rectangle and the distribution shapes of the second partial light and the third partial light are closer to a rectangle than to a triangle. If the change in the light intensity is gradual, it is possible to employ a method of overlapping lights as entirely as possible besides a method of not overlapping lights too much, but in consideration of the symmetry, a triangle is not suitable for the method of overlapping lights entirely as much as possible.

The smallest triangle that encloses the distribution shape of the first partial light of the first light on the incident surface 83 (hereinafter, referred to as an enclosing triangle) is a shape close to a right triangle. Further, the enclosing triangle has a shape close to a right triangle having the third side and the fourth side of the enclosing rectangle based on the first light. With such a distribution shape, the first partial light of the first semiconductor laser element 20A and the first partial light of the second semiconductor laser element 20B are emitted to the incident surface 83 so as not to overlap each other too much, whereby the uniformity of the combined light of the first partial lights can be improved. Specifically, the following condition is satisfied: in the enclosing triangle, the angle formed by the side closest to parallel to the third side and the side closest to parallel to the fourth side is in a range of 75 degrees to 105 degrees, and this angle is the largest among the three interior angles in the enclosing triangle. The first partial light of the second light, the fourth partial light of the first light, and the fourth partial light of the second light may also satisfy similar conditions.

The plurality of semiconductor laser elements 20 are disposed in a closed space of the light-emitting device 1. The closed space is formed by joining the base 10 and the light transmissive member 82. The light transmissive member 82 can serve as a lid member. In the illustrated example of the light-emitting device 1, the closed space is formed in a hermetically sealed state. When the closed space is hermetically sealed, it is possible to suppress collection of organic matters and the like on the light-emitting surface of the semiconductor laser element.

In the light-emitting device 1, the light blocking member 90 is formed filling the gap between the base 10 and the wavelength conversion member 81. The light blocking member 90 can be formed by, for example, pouring a thermosetting resin and curing the resin with heat. By providing the light blocking member 90, leakage of light from a place other than the light extraction surface is suppressed.

The light blocking member 90 does not reach the upper surface of the wavelength conversion member 81. Accordingly, it is possible to provide the light blocking member 90 filling the gap while avoiding the wavelength conversion portion 811 that is the light extraction surface, and it is possible to reduce the leakage of light from a place other than the light extraction surface.

Although the embodiments according to the present invention have been described above, the light-emitting device according to the present invention is not strictly limited to the light-emitting devices of the embodiments. In other words, the present invention may be achieved without being limited to the external shape or structure of the light-emitting device disclosed by each of the embodiments. The present invention can be applied without requiring all the components to be provided. For example, in a case in which some of the components of the light-emitting device disclosed by the embodiments are not stated in the claims, the degree of freedom in design by those skilled in the art such as substitutions, omissions, shape modifications, and material changes for those components is allowed, and then the invention stated in the claims being applied to those components is specified.

Throughout the contents described in this description, the following technical matters are disclosed.

### Supplementary Note 1

A light-emitting device including: a first semiconductor laser element configured to emit first light having a divergence angle of 15 degrees or more and less than 90 degrees in a fast axis direction and a divergence angle of more than 0 degrees and 8 degrees or less in a slow axis direction;
a first light reflecting member having at least four light reflecting surfaces sequentially connected in an order of proximity to the first semiconductor laser element;
a second semiconductor laser element configured to emit second light having a divergence angle of 15 degrees or more and less than 90 degrees in a fast axis direction and a divergence angle of more than 0 degrees and 8 degrees or less in a slow axis direction;
a second light reflecting member having at least four light reflecting surfaces sequentially connected in an order of proximity to the second semiconductor laser element; and
a wavelength conversion member having an incident surface on which the first light reflected by the first light reflecting member and the second light reflected by the second light reflecting member are incident, wherein
each part of a main portion of the first light emitted from the first semiconductor laser element is reflected by at least one of the at least four light reflecting surfaces of the first light reflecting member,
each part of a main portion of the second light emitted from the second semiconductor laser element is reflected by at least one of the at least four light reflecting surfaces of the second light reflecting member,
a light intensity distribution in the fast axis direction of the first light on the incident surface of the wavelength conversion member is more uniform than a light intensity distribution in a fast axis direction of a far-field pattern of the first semiconductor laser element,
a light intensity distribution in the fast axis direction of the second light on the incident surface of the wavelength conversion member is more uniform than a light intensity distribution in a fast axis direction of a far-field pattern of the second semiconductor laser element, and
in a state where the first light and the second light are combined on the incident surface of the wavelength conversion member, 93% or more of a sum of a light output of the first light and a light output of the second light is emitted to a region of a 0.5 mm square on the incident surface of the wavelength conversion member.

### Supplementary Note 2

The light-emitting device according to Supplementary Note 1, wherein
the farther one of the at least four light reflecting surfaces of the first light reflecting member is from the first semiconductor laser element, the larger a width of the one of the at least four light reflecting surfaces of the first light reflecting member is, and
   the farther one of the at least four light reflecting surfaces of the second light reflecting member is, the larger a width of the one of the at least four light reflecting surfaces of the second light reflecting member is.

### Supplementary Note 3

The light-emitting device according to Supplementary Note 1 or 2, wherein
the at least four light reflecting surfaces of the first light reflecting member have a first light reflecting surface, a second light reflecting surface, a third light reflecting surface, and a fourth light reflecting surface in order of proximity to the first semiconductor laser element,
each of the first light reflecting surface, the second light reflecting surface, the third light reflecting surface, and the fourth light reflecting surface is inclined with respect to a lower surface of the light reflecting member,
a difference between an inclination angle of the first light reflecting surface and an inclination angle of the second light reflecting surface is in a range of 8 degrees to 14 degrees,
   a difference between the inclination angle of the second light reflecting surface and an inclination angle of the third light reflecting surface is in a range of 9 degrees to 15 degrees, and
   a difference between the inclination angle of the third light reflecting surface and an inclination angle of the fourth light reflecting surface is in a range of 10 degrees to 16 degrees.

### Supplementary Note 4

The light-emitting device according to any one of Supplementary Notes 1 to 3, wherein the at least four light reflecting surfaces of the first light reflecting member have a first light reflecting surface, a second light reflecting surface, a third light reflecting surface, and a fourth light reflecting surface in order of proximity to the first semiconductor laser element,
each of the first light reflecting surface, the second light reflecting surface, the third light reflecting surface, and the fourth light reflecting surface is inclined with respect to a lower surface of the light reflecting member, and
   a difference between an inclination angle of the first light reflecting surface and an inclination angle of the second light reflecting surface is smaller than a difference between the inclination angle of the second light reflecting surface and an inclination angle of the third light reflecting surface.

### Supplementary Note 5

The light-emitting device according to any one of Supplementary Notes 1 to 4, wherein a wavelength conversion portion having the incident surface and an emission surface opposite to the incident surface, the wavelength conversion portion containing a phosphor, and
a surrounding portion having a first surface surrounding the incident surface in a plan view seen from a direction perpendicular to the incident surface, and a second surface surrounding the emission surface in a plan view seen from a direction perpendicular to the emission surface, and
the incident surface does not protrude from a 0.75 mm square in the plan view.

### Supplementary Note 6

The light-emitting device according to any one of Supplementary Notes 1 to 5, wherein an outer shape of the incident surface of the wavelength conversion member is a rectangle having a first side and a second side perpendicular to the first side, and a length of the first side is in a range of 1.0 times to 1.5 times a length of the second side.

### Supplementary Note 7

The light-emitting device according to Supplementary Note 6, wherein
a virtual straight line connecting points on the incident surface of the wavelength conversion member to which first end light and second end light passing through both ends in a fast axis direction of a far-field pattern of the first light emitted from the first semiconductor laser element are emitted is substantially parallel to the first side.

### Supplementary Note 8

The light-emitting device according to any one of Supplementary Notes 1 to 7, wherein the at least four light reflecting surfaces of the first light reflecting member have a first light reflecting surface, a second light reflecting surface, a third light reflecting surface, and a fourth light reflecting surface in order of proximity to the first semiconductor laser element,
the at least four light reflecting surfaces of the second light reflecting member have a fifth light reflecting surface, a sixth light reflecting surface, a seventh light reflecting surface, and an eighth light reflecting surface in order of proximity to the second semiconductor laser element, and
an area of an overlap between a first region of the incident surface of the wavelength conversion member that is irradiated with a part of the main portion of the first light reflected by the first light reflecting surface and a region of the incident surface of the wavelength conversion member that is irradiated with a part of the main portion of the second light reflected by the fifth light reflecting surface is in a range of 0% to 60% of an area of the first region.

### Supplementary Note 9

The light-emitting device according to Supplementary Note 8, wherein
an area of an overlap between a second region of the incident surface of the wavelength conversion member that is irradiated with a part of the main portion of the first light reflected by the second light reflecting surface and a region of the incident surface of the wavelength conversion member that is irradiated with a part of the main portion of the second light reflected by the sixth light reflecting surface is 75% or more and less than 100% of the area of the second region.

The light-emitting devices according to the embodiments can be used for an in-vehicle headlight, a head-mounted display, a lighting, a projector, a display, and the like.

What is claimed is:

1. A light-emitting device comprising:
a first semiconductor laser element configured to emit first light having a divergence angle of 15 degrees or more and less than 90 degrees in a fast axis direction and a divergence angle of more than 0 degrees and 8 degrees or less in a slow axis direction;
a first light reflecting member having at least four light reflecting surfaces sequentially connected in an order of proximity to the first semiconductor laser element;
a second semiconductor laser element configured to emit second light having a divergence angle of 15 degrees or more and less than 90 degrees in a fast axis direction and a divergence angle of more than 0 degrees and 8 degrees or less in a slow axis direction;
a second light reflecting member having at least four light reflecting surfaces sequentially connected in an order of proximity to the second semiconductor laser element; and
a wavelength conversion member having an incident surface on which the first light reflected by the first light reflecting member and the second light reflected by the second light reflecting member are incident, wherein
each part of a main portion of the first light emitted from the first semiconductor laser element is reflected by at least one of the at least four light reflecting surfaces of the first light reflecting member,
each part of a main portion of the second light emitted from the second semiconductor laser element is reflected by at least one of the at least four light reflecting surfaces of the second light reflecting member,
a light intensity distribution in the fast axis direction of the first light on the incident surface of the wavelength conversion member is more uniform than a light intensity distribution in a fast axis direction of a far-field pattern of the first semiconductor laser element,
a light intensity distribution in the fast axis direction of the second light on the incident surface of the wavelength conversion member is more uniform than a light intensity distribution in a fast axis direction of a far-field pattern of the second semiconductor laser element, and
in a state where the first light and the second light are combined on the incident surface of the wavelength conversion member, 93% or more of a sum of a light output of the first light and a light output of the second light is emitted to a region of a 0.5 mm square on the incident surface of the wavelength conversion member.

2. The light-emitting device according to claim 1, wherein
the farther one of the at least four light reflecting surfaces of the first light reflecting member is from the first semiconductor laser element, the larger a width of the one of the at least four light reflecting surfaces of the first light reflecting member is, and
the farther one of the at least four light reflecting surfaces of the second light reflecting member is, the larger a width of the one of the at least four light reflecting surfaces of the second light reflecting member is.

3. The light-emitting device according to claim 1, wherein
the at least four light reflecting surfaces of the first light reflecting member have a first light reflecting surface, a second light reflecting surface, a third light reflecting surface, and a fourth light reflecting surface in order of proximity to the first semiconductor laser element,
each of the first light reflecting surface, the second light reflecting surface, the third light reflecting surface, and the fourth light reflecting surface is inclined with respect to a lower surface of the light reflecting member,
a difference between an inclination angle of the first light reflecting surface and an inclination angle of the second light reflecting surface is in a range of 8 degrees to 14 degrees,
a difference between the inclination angle of the second light reflecting surface and an inclination angle of the third light reflecting surface is in a range of 9 degrees to 15 degrees, and
a difference between the inclination angle of the third light reflecting surface and an inclination angle of the fourth light reflecting surface is in a range of 10 degrees to 16 degrees.

4. The light-emitting device according to claim 1, wherein
the at least four light reflecting surfaces of the first light reflecting member have a first light reflecting surface, a second light reflecting surface, a third light reflecting surface, and a fourth light reflecting surface in order of proximity to the first semiconductor laser element,
each of the first light reflecting surface, the second light reflecting surface, the third light reflecting surface, and the fourth light reflecting surface is inclined with respect to a lower surface of the light reflecting member, and
a difference between an inclination angle of the first light reflecting surface and an inclination angle of the second light reflecting surface is smaller than a difference between the inclination angle of the second light reflecting surface and an inclination angle of the third light reflecting surface.

5. The light-emitting device according to claim 1, wherein
the wavelength conversion member includes
a wavelength conversion portion having the incident surface and an emission surface opposite to the incident surface, the wavelength conversion portion containing a phosphor, and
a surrounding portion having a first surface surrounding the incident surface in a plan view seen from a direction perpendicular to the incident surface, and a second surface surrounding the emission surface in a plan view seen from a direction perpendicular to the emission surface, and
the incident surface does not protrude from a 0.75 mm square in the plan view.

6. The light-emitting device according to claim 5, wherein
an outer shape of the incident surface of the wavelength conversion member is a rectangle having a first side and a second side perpendicular to the first side, and a length of the first side is in a range of 1.0 times to 1.5 times a length of the second side.

7. The light-emitting device according to claim 6, wherein
a virtual straight line connecting points on the incident surface of the wavelength conversion member to which first end light and second end light passing through both ends in a fast axis direction of a far-field pattern of the first light emitted from the first semiconductor laser element are emitted is substantially parallel to the first side.

8. The light-emitting device according to claim 1, wherein
the at least four light reflecting surfaces of the first light reflecting member have a first light reflecting surface, a second light reflecting surface, a third light reflecting surface, and a fourth light reflecting surface in order of proximity to the first semiconductor laser element,
the at least four light reflecting surfaces of the second light reflecting member have a fifth light reflecting surface, a sixth light reflecting surface, a seventh light reflecting surface, and an eighth light reflecting surface in order of proximity to the second semiconductor laser element, and
an area of an overlap between a first region of the incident surface of the wavelength conversion member that is irradiated with a part of the main portion of the first light reflected by the first light reflecting surface and a region of the incident surface of the wavelength conversion member that is irradiated with a part of the main portion of the second light reflected by the fifth light reflecting surface is in a range of 0% to 60% of an area of the first region.

9. The light-emitting device according to claim 8, wherein
an area of an overlap between a second region of the incident surface of the wavelength conversion member that is irradiated with a part of the main portion of the first light reflected by the second light reflecting surface and a region of the incident surface of the wavelength conversion member that is irradiated with a part of the main portion of the second light reflected by the sixth light reflecting surface is 75% or more and less than 100% of the area of the second region.
